(19) United States
(12) Patent Application Publication
(10) Pub. No.: US 2025/0151536 A1
(43) Pub. Date: May 8, 2025

(54) DISPLAY DEVICE AND METHOD FOR MANUFACTURING THE SAME

(71) Applicant: Samsung Display Co., LTD., Yongin-si (KR)

(72) Inventors: Hyun Jung LEE, Yongin-si (KR); Jun Hwi LIM, Yongin-si (KR)

(73) Assignee: Samsung Display Co., LTD., Yongin-si (KR)

(21) Appl. No.: 18/784,329

(22) Filed: Jul. 25, 2024

(30) Foreign Application Priority Data
Nov. 2, 2023 (KR) 10-2023-0149569

(51) Int. Cl. H10K 59/124; H10K 59/12; H10K 59/121

(52) U.S. Cl. CPC H10K 59/124; H10K 59/1201; H10K 59/1213

(57) ABSTRACT

A display device includes a first electrode, a buffer layer disposed on the first electrode, a first transistor including a first active layer disposed on the buffer layer and a first gate electrode disposed on a part of the first active layer, a second electrode disposed on the buffer layer and electrically connected to the first electrode, a first gate insulating layer disposed between the first active layer and the first gate electrode, an area of a top surface of the first gate insulating layer may be larger than an area of a bottom surface of the first gate electrode in a plan view, and the first gate insulating layer protrudes to an outside of the first gate electrode, and a second gate insulating layer disposed between the buffer layer and the second electrode, the second gate insulating layer and the first gate insulating layer include a same material.

### CROSS-REFERENCE TO RELATED APPLICATIONS

This application claims priority under 35 U.S.C. § 119 from Korean Patent Application No. 10-2023-0149569 filed on Nov. 2, 2023 in the Korean Intellectual Property Office, the entire contents of which are incorporated herein by reference.

### BACKGROUND

### 1. Technical Field

The disclosure relates to a display device and a method for manufacturing the same.

### 2. Description of the Related Art

The importance of display devices has steadily increased with the development of multimedia technology. Along with this trend, various display devices including a light emitting display device are being developed.

### SUMMARY

Aspects of the disclosure provide a display device capable of improving operating characteristics of a transistor and simplifying a manufacturing process, and a method for manufacturing the same.

However, aspects of the disclosure may not be restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device that may include a first electrode disposed on a substrate, a buffer layer disposed on the first electrode, a first transistor including a first active layer disposed on the buffer layer and a first gate electrode disposed on a part of the first active layer, a second electrode disposed on the buffer layer and electrically connected to the first electrode, a first gate insulating layer disposed between the first active layer and the first gate electrode, wherein in a plan view, an area of a top surface of the first gate insulating layer may be larger than an area of a bottom surface of the first gate electrode, and the first gate insulating layer may protrude to an outside of the first gate electrode, and a second gate insulating layer may be disposed between the buffer layer and the second electrode, the second gate insulating layer and the first gate insulating layer may include a same material.

In an embodiment and in a plan view, the first active layer may include a channel region overlapping the first gate electrode, and a source region and a drain region located at both sides of the channel region, and in a lengthwise direction of the channel region, the first gate electrode may have a first length, and the first gate insulating layer may have a second length longer than the first length.

In an embodiment and in a plan view, the first gate insulating layer may overlap only a part of the first active layer and may expose another part of the first active layer.

In an embodiment, the first gate insulating layer and the second gate insulating layer may be separated from each other.

In an embodiment, the display device may further include, a second transistor including a second active layer disposed on the buffer layer and a second gate electrode disposed on a part of the second active layer, and a third gate insulating layer disposed between the second active layer and the second gate electrode, wherein in a plan view, an area of a top surface of the third gate insulating layer may be larger than an area of a bottom surface of the second gate electrode, and the third gate insulating layer may protrude to an outside of the second gate electrode.

In an embodiment, the third gate insulating layer and the first gate insulating layer may include a same material, the third gate insulating layer may be separated from the first gate insulating layer.

In an embodiment and in a plan view, the first gate insulating layer may overlap only a part of the first active layer and may expose another part of the first active layer, and the third gate insulating layer may overlap only a part of the second active layer and may expose another part of the second active layer.

In an embodiment, the first gate insulating layer may entirely cover the first active layer, and the third gate insulating layer may overlap only a part of the second active layer and may expose another part of the second active layer.

In an embodiment, the first gate insulating layer and the second gate insulating layer may be integral with each other.

In an embodiment, the first active layer and the second active layer may include a same oxide semiconductor.

In an embodiment, the display device may further include a barrier layer disposed between the first electrode and the buffer layer, the barrier layer may cover the first electrode in a plan view, and a bottom gate electrode may be disposed between the barrier layer and the buffer layer and may overlap the first active layer in a plan view.

In an embodiment, the second electrode may be electrically connected to the first electrode through a contact hole penetrating the barrier layer, the buffer layer, and the second gate insulating layer.

In an embodiment, the bottom gate electrode may face the first gate electrode with the first active layer disposed therebetween, the bottom gate electrode may be electrically connected to an electrode of the first transistor.

In an embodiment, the display device may further include a first insulating layer disposed on the buffer layer and covering the first active layer, the first gate insulating layer, the second gate insulating layer, the first gate electrode, and the second electrode.

In an embodiment, the first transistor may further include at least one of a source electrode disposed on the first insulating layer and electrically connected to a part of the first active layer, or a drain electrode disposed on the first insulating layer and electrically connected to another part of the first active layer.

In an embodiment, the display device may further include a second insulating layer disposed on the first insulating layer and covering the first transistor, a light emitting element layer including a light emitting element disposed on the second insulating layer, and an encapsulation layer covering the light emitting element layer.

According to an aspect of the disclosure, there may be provided a method for manufacturing a display device, including forming a first electrode on a substrate, forming a buffer layer on the substrate to cover the first electrode, forming an active layer on the buffer layer, forming a gate insulating layer on the buffer layer to cover the active layer, disposing a mask on the gate insulating layer, the mask may overlap a part of each of the active layer and the first electrode, etching the gate insulating layer using the mask to expose another part of the active layer and to form a contact hole penetrating the gate insulating layer and the buffer layer, the contact hole may expose a part of the first electrode, and forming a gate electrode and a second electrode on the gate insulating layer, the gate electrode may overlap the part of the active layer, the second electrode may be electrically connected to the part of the first electrode through the contact hole.

In an embodiment, the method may further include, before the forming of the buffer layer, forming a barrier layer on the substrate to cover the first electrode and forming a bottom gate electrode on the barrier layer, wherein the buffer layer may be formed on the barrier layer to cover the bottom gate electrode.

In an embodiment, the contact hole may be formed to penetrate the gate insulating layer, the buffer layer, and the barrier layer.

In an embodiment, the etching of the gate insulating layer using the mask may form a first gate insulating layer overlapping the part of the active layer and a second gate insulating layer overlapping the part of the first electrode.

A display device according to embodiments may a transistor including an active layer and a gate electrode on the active layer, and a gate insulating layer disposed between the active layer and the gate electrode and protruding to the outside of the gate electrode while having a larger area than the lower surface of the gate electrode. The gate insulating layer may cover not only a channel region of the active layer overlapping the gate electrode but also a portion of each of a source region and a drain region not overlapping the gate electrode. Accordingly, the effective channel length of the transistor may be sufficiently secured, and the operating characteristics of the transistor may be improved and/or secured.

In embodiments, the gate electrode and the gate insulating layer may be individually patterned through individual etching processes using different masks. Accordingly, the gate electrode and the active layer of the transistor may be stably insulated, and a short circuit defect of the transistor may be prevented.

In embodiments, the display device may further include a first electrode disposed under the transistor, and a second electrode disposed on the first electrode and electrically connected to the first electrode. The gate insulating layer may be etched in a mask process to form a contact hole connecting the first electrode and the second electrode. Accordingly, a mask process for patterning the gate electrode and a mask process for patterning the gate insulating layer may be separated without adding an additional mask process. Furthermore, without adding an additional mask process, the gate insulating layer may be differentially and/or selectively etched as required for each transistor.

With the display device and the manufacturing method therefor according to the embodiments, it may be possible to simplify and/or streamline the manufacturing process of the display device while improving the operating characteristics of the transistor belonging to the display device. As a result, the manufacturing efficiency of the display device may be improved.

However, effects according to the embodiments of the disclosure may not be limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a plan view illustrating a display device according to an embodiment;

FIG. 2 is a plan view illustrating a display panel of FIG. 1;

FIG. 3 is a schematic cross-sectional view illustrating the display panel according to an embodiment;

FIG. 4 is a schematic cross-sectional view illustrating the display panel according to an embodiment; and

FIGS. 5 to 12 are schematic cross-sectional views showing a method for manufacturing the display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

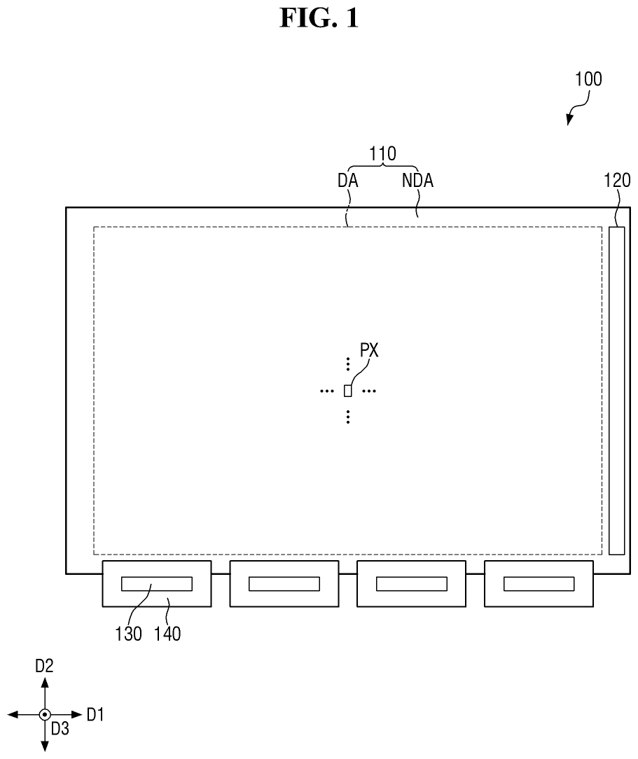

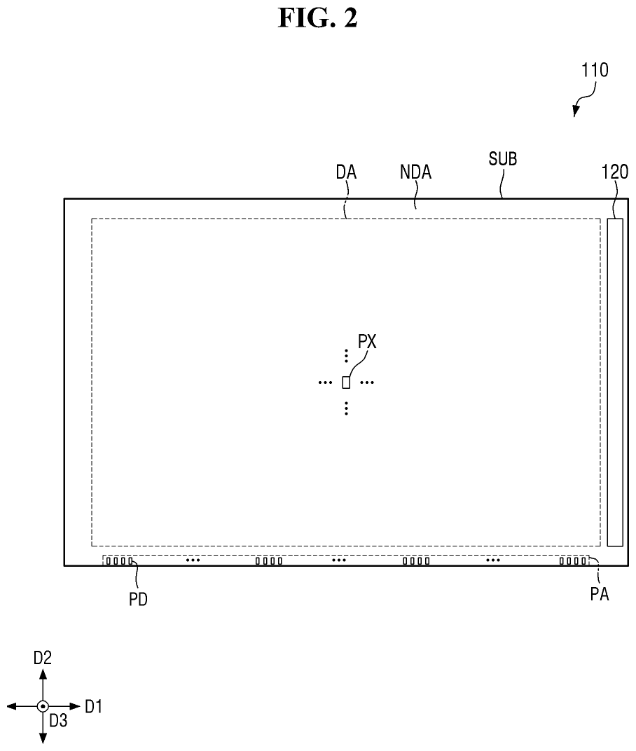

FIG. 1 is a plan view illustrating a display device 100 according to an embodiment. FIG. 2 is a plan view illustrating a display panel 110 of FIG. 1.

Referring to FIGS. 1 and 2, the display device 100 may be a device for displaying a moving image or a still image. The display device 100 may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). These may be presented as nothing more than examples, and the display device 100 may be applicable to various other types of electronic devices.

In an embodiment, the display device 100 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display using an ultra-small light emitting diode such as a micro or nano light emitting diode (micro LED or nano LED), but is not limited thereto. For example, the display device 100 may be another type of display device other than a light emitting display device. In the following, embodiments in which the display device 100 may be an organic light emitting display device will be disclosed.

The display device 100 may include the display panel 110 including pixels PX, and a first driver 120 and a second driver 130 configured to supply driving signals to the pixels PX. The display device 100 may further include additional components. For example, the display device 100 may further include a power supply part for supplying power voltages to the pixels PX, the first driver 120, and the second driver 130, and a timing controller for controlling the operations of the first driver 120 and the second driver 130.

The display panel 110 may include a display area DA and a non-display area NDA. The display area DA may be an area including the pixels PX to display an image. The non-display area NDA may be an area other than the display area DA, and an image may not be displayed in the non-display area NDA. In an embodiment, the non-display area NDA may be positioned around the display area DA and may surround the display area DA.

In FIGS. 1 and 2, a first direction D1, a second direction D2, and a third direction D3 may be defined. In an embodiment, the first direction D1 may be the horizontal direction (for example, a row direction or X direction) of the display panel 110, and the second direction D2 may be the vertical direction (for example, a column direction or Y direction) of the display panel 110. The third direction D3 may be the thickness direction (for example, a height direction or Z direction) of the display panel 110.

In an embodiment, the display panel 110 may have a rectangular shape in a plan view. Although FIGS. 1 and 2 illustrate the display panel 110 with a horizontal length longer than a vertical length, the shape of the display panel 110 is not limited thereto. For example, the display panel 110 may have a shape with a vertical length longer than a horizontal length, a square shape, or the like. The display panel 110 may include an angled corner or a rounded corner.

The planar shape of the display panel 110 may not be limited to the illustrated quadrilateral shape, and it may be applied in other shapes. For example, the display panel 110 may have a non-quadrilateral polygonal shape, a circular shape, an elliptical shape, an atypical shape, or another shape in a plan view.

In an embodiment, the display panel 110 may be approximately flat on the plane defined by the first direction D1 and the second direction D2, and may have a uniform thickness in the third direction D3. The display panel 110 may be provided in a three-dimensional shape having a curved surface or the like.

The display panel 110 may be provided as a rigid panel so as not to be substantially transformed, or as a flexible panel that can be transformed to be at least partially folded, bent, or rolled. The display panel 110 may be provided to the display device 100 without bending, or may be provided to the display device 100 while being partially bent.

The display panel 110 may include a substrate SUB and pixels PX disposed on the substrate SUB. The pixels PX may be disposed in the display area DA on the substrate SUB.

The substrate SUB, which may be a base member for manufacturing or providing the display panel 110, may form the base surface of the display panel 110. The substrate SUB may include the display area DA and the non-display area NDA around the display area DA.

The display area DA may have various shapes depending on embodiments. For example, the display area DA may have a quadrilateral shape, a non-quadrilateral polygonal shape, a circular shape, an elliptical shape, an atypical shape, or another shape. In an embodiment, the display area DA may have a shape corresponding to the shape of the display panel 110, but the disclosure may not be limited thereto.

The pixels PX may be provided and/or arranged in the display area DA. For example, the display area DA may include multiple pixel areas in which the respective pixels PX may be disposed.

In an embodiment, the display device 100 may be a light emitting display device, and each pixel PX may include a light emitting element located in each emission area and a pixel circuit electrically connected to the light emitting element. In describing embodiments, the term “connect” may include electrical connection and/or physical connection. Each pixel circuit may include transistors (for example, a driving transistor that generates a driving current corresponding to a data signal, and pixel transistors including at least one switching transistor) and at least one capacitor (for example, a storage capacitor).

The non-display area NDA may include a pad area PA in which pads PD may be disposed, and may selectively further include a driving circuit area. The driving circuit area may be located on at least one side of the display area DA. At least one driver, the pads PD, and/or wires may be disposed in the non-display area NDA.

At least one driver for driving the pixels PX, or a part of the driver may be disposed in the driving circuit area. For example, circuit elements constituting the first driver 120 (e.g., driver transistors and driver capacitors constituting the stage circuits of the first driver 120) may be disposed in the driving circuit area on the substrate SUB. In an embodiment, the circuit elements of the first driver 120 may be formed in the display panel 110 together with the pixels PX.

The pads PD may be disposed in the pad area PA. At least one circuit board 140 may be disposed and/or bonded on the pad area PA. In an embodiment, multiple circuit boards 140 electrically connected to different pads PD may be disposed on the pad area PA. The pads PD may include signal pads and power pads for transmitting driving signals and power voltages required for driving the pixels PX and/or the first driver 120 into the display panel 110.

The first driver 120 and the second driver 130 may generate driving signals for controlling operation timing, luminance, and the like of the pixels PX, and may supply the generated driving signals to the pixels PX. For example, the first driver 120 may be a gate driver including a scan driver, and may be electrically connected to the pixels PX through respective gate lines. The first driver 120 may supply respective gate signals (e.g., control signals for controlling the driving timing of the pixels PX, including scan signals and/or emission control signals) to the pixels PX. The second driver 130 may be a data driver including source driving circuits, and may be electrically connected to the pixels PX through respective data lines. The second driver 130 may supply respective data signals to the pixels PX.

In an embodiment, at least one first driver of the first driver 120 or the second driver 130, or a part of the at least one first driver may be embedded in the display panel 110. For example, the first driver 120 or a part of the first driver 120 may be disposed and/or formed in the non-display area NDA and disposed on the substrate SUB of the display panel 110.

Although FIG. 1 illustrates that the first driver 120 may be formed at a side of the display area DA (for example, in the non-display area NDA at the right side of the display area DA), but the embodiments may not be limited thereto. For example, the first driver 120 may be positioned only at another side (e.g., the non-display area NDA at the left side of the display area DA) of the display area DA, or may be positioned at both sides (e.g., the non-display area NDA at the left side and right side of the display area DA) of the display area DA. A part of the first driver 120 may be portioned in the non-display area NDA, and another part of the first driver 120 may be positioned in a non-emission area (e.g., an area between emission areas of the pixels PX) inside the display area DA.

In an embodiment, another driver of the first driver 120 and the second driver 130 or a part of another driver may be disposed or formed outside the display panel 110 to be electrically connected to the display panel 110. For example, the second driver 130 may be implemented as a multiple number of integrated circuit chips, which may be disposed on the circuit boards 140 electrically connected to the pixels PX of the display panel 110. The second driver 130 may be implemented as at least one integrated circuit chip and mounted on the non-display area NDA of the display panel 110.

The circuit board 140 may be electrically connected to the display panel 110 through the pads PD. In an embodiment, the circuit board 140 may be a flexible film such as a flexible printed circuit board (FPCB), a printed circuit board (PCB), or a chip on film (COF), but may not be limited thereto. In an embodiment, the circuit board 140 may be electrically connected to the timing controller and/or the power supply part through another circuit board, connector, or the like.

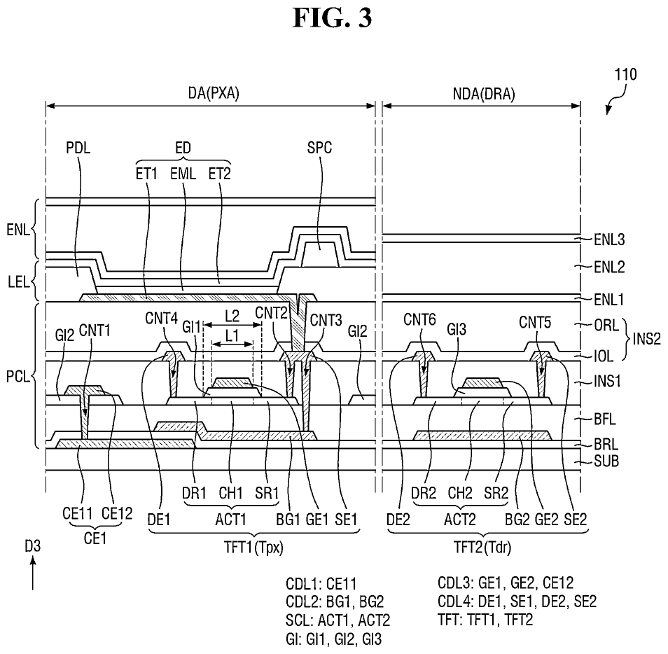

FIG. 3 is a schematic cross-sectional view illustrating the display panel 110 according to an embodiment. For example, FIG. 3 illustrates a part of the display area DA and a part of the non-display area NDA of the display panel 110. FIG. 3 illustrates a light emitting display panel including a light emitting element ED (for example, an organic light emitting diode) as an example of the display panel 110 to which embodiments may be applied.

Referring to FIG. 3 in addition to FIGS. 1 and 2, the display panel 110 may include the substrate SUB (also referred to as “base layer”), a panel circuit layer PCL, a light emitting element layer LEL, and an encapsulation layer ENL. The panel circuit layer PCL, the light emitting element layer LEL, and the encapsulation layer ENL may be disposed to overlap each other on the substrate SUB. For example, with respect to the display area DA, the panel circuit layer PCL, the light emitting element layer LEL, and the encapsulation layer ENL may be sequentially disposed on the substrate SUB in the third direction D3. However, the embodiments may not be limited thereto, and the positions of the panel circuit layer PCL, the light emitting element layer LEL, and/or the encapsulation layer ENL may be changed.

In an embodiment, the display panel 110 may further include additional elements provided above and/or under the encapsulation layer ENL. For example, the display panel 110 may further include at least one of a sensor layer (for example, a touch sensor layer), an optical layer (for example, a color filter layer and/or a wavelength conversion layer), or a passivation layer (for example, a passivation film, an insulating layer, an upper substrate, and/or a window). Each of the sensor layer, the optical layer, and/or the passivation layer may be provided above the encapsulation layer ENL or may be provided between the light emitting element layer LEL and the encapsulation layer ENL.

The substrate SUB may be a base member for forming the display panel 110 and may be a rigid or flexible substrate (or film). In an embodiment, the substrate SUB may be a substrate including an insulating material such as glass or the like and having rigid characteristics, and may not be bent. The substrate SUB may be a flexible substrate that includes polyimide or another insulating material and may be transformed to be bent, folded, or rolled, and may or may not be bent. The type and/or material of the substrate SUB may change depending on embodiments.

The substrate SUB may include the display area DA and the non-display area NDA. In an embodiment, the display area DA may include the pixel areas PXA corresponding to the pixels PX, and the non-display area NDA may include a driving circuit area DRA. For example, the pixel areas PXA where the pixels PX may be disposed may be defined in the display area DA, and the driving circuit area DRA where the first driver 120 may be disposed may be defined in the non-display area NDA.

The panel circuit layer PCL may be disposed on the substrate SUB. The panel circuit layer PCL may include circuit elements including pixel transistors Tpx and driving transistors Tdr, and wires (e.g., signal lines and power lines). In an embodiment, the panel circuit layer PCL may further include additional conductive patterns (e.g., bridge patterns).

The pixel transistors Tpx may be included in the pixel circuit of each pixel PX, and may be positioned in the display area DA. For example, each pixel transistor Tpx may be disposed in the pixel area PXA in which the corresponding pixel PX may be located. In FIG. 3, on behalf of the pixel transistors Tpx, a pixel transistor Tpx (e.g., the pixel transistor Tpx electrically connected to the light emitting element ED of the corresponding pixel PX) may be illustrated, and this will be referred to as “first transistor TFT1.”

The driver transistors Tdr may be included in the first driver 120, or the like, and may be located in the driver circuit area DRA. In an embodiment, the driving circuit area DRA may be located in the non-display area NDA. In FIG. 3, only one driver transistor Tdr may be illustrated to represent the driver transistors Tdr, and this will be referred to as the “second transistor TFT2.”

Each transistor TFT (e.g., the first transistor TFT1 or the second transistor TFT2) may include an active layer (e.g., a first active layer ACT1 or a second active layer ACT2) and a gate electrode (e.g., a first gate electrode GE1 or a second gate electrode GE2) disposed on the active layer. In an embodiment, each transistor TFT may further include at least one of a bottom gate electrode (e.g., a first bottom gate electrode BG1 or a second bottom gate electrode BG2), a source electrode (e.g., a first source electrode SE1 or a second source electrode SE2), or a drain electrode (e.g., a first drain electrode DE1 or a second drain electrode DE2).

The pixel circuit of each pixel PX may further include at least one capacitor. For example, a first capacitor electrode CEI (also referred to as “capacitor electrode”) may be disposed in each pixel area PXA. In an embodiment, at least one electrode (e.g., the first bottom gate electrode BG1 and/or the first source electrode SE1) of the first transistor TFT1, and/or the first active layer ACT1 of the first transistor TFT1 may form a capacitance between them and the first capacitor electrode CE1. Accordingly, at least one electrode of the first transistor TFT1 and/or the first active layer ACT1 may constitute a second capacitor electrode. For example, each pixel PX may include a capacitor (e.g., a storage capacitor) including the first capacitor electrode CE1 and the second capacitor electrode, and the second capacitor electrode and at least one electrode of the first transistor TFT1 and/or the first active layer ACT1 may be integral with each other.

The panel circuit layer PCL may further include multiple insulating layers disposed on the substrate SUB. For example, the panel circuit layer PCL may include a barrier layer BRL, a buffer layer BFL, a gate insulating layer GI, a first insulating layer INS1 (e.g., an interlayer insulating layer), and a second insulating layer INS2 (e.g., a passivation layer) sequentially disposed on the substrate SUB in the third direction D3.

In an embodiment, at least one insulating layer provided in the panel circuit layer PCL may be entirely disposed in the display area DA and/or driving circuit area DRA. For example, the barrier layer BRL, the buffer layer BFL, the first insulating layer INS1 and the second insulating layer INS2 may be entirely disposed in the display area DA and the driving circuit area DRA.

In an embodiment, the gate insulating layer GI may include insulating patterns partially disposed in the display area DA and the driving circuit area DRA. For example, the gate insulating layer GI may include insulating patterns disposed on a part of each of the active layers of the pixel transistors Tpx and the driver transistors Tdr. In an embodiment, the gate insulating layer GI may include a first gate insulating layer GI1 (also referred to as “first gate insulating pattern”) and a second gate insulating layer GI2 (also referred to as “second gate insulating pattern”) located in the display area DA, and a third gate insulating layer GI3 (also referred to as “third gate insulating pattern”) located in the driving circuit area DRA. However, embodiments may not be limited thereto. For example, the gate insulating layer GI may be entirely disposed in the display area DA or the driving circuit area DRA.

The first gate insulating layer GI1 may be disposed on a part of the first active layer ACT1 of the first transistor TFT1. The first gate insulating layer GI1 may expose another part of the first active layer ACT1.

The second gate insulating layer GI2 may be positioned in an area of each pixel area PXA. In an embodiment, the second gate insulating layer GI2 may be disposed under at least a second electrode CE12 of the first capacitor electrode CE1. For example, the second gate insulating layer GI2 may be disposed between the second electrode CE12 of the first capacitor electrode CEI and the buffer layer BFL. In an embodiment, the second gate insulating layer GI2 may be separated from the first gate insulating layer GI1 in each pixel area PXA and/or the display area DA. For example, the first gate insulating layer GI1 and the second gate insulating layer GI2 may be formed as individual patterns that may be separated from each other.

The third gate insulating layer GI3 may be disposed on a part of the second active layer ACT2 of the second transistor TFT2. The third gate insulating layer GI3 may expose another part of the second active layer ACT2. In an embodiment, the third gate insulating layer GI3 may be separated from the first gate insulating layer GI1 and/or the second gate insulating layer GI2. By way of example, the third gate insulating layer GI3 may be formed as an insulating pattern spaced apart from the first gate insulating layer GI1 and the second gate insulating layer GI2.

In an embodiment, the first gate insulating layer GI1, the second gate insulating layer GI2, and the third gate insulating layer GI3 may be simultaneously formed by a process of forming an insulating film using the same insulating material and a process of patterning the insulating film. Accordingly, the first gate insulating layer GI1, the second gate insulating layer GI2, and the third gate insulating layer GI3 may be disposed and/or formed on substantially a same layer and may include a same material.

In an embodiment, the gate insulating layer GI to be patterned into the first gate insulating layer GI1, the second gate insulating layer GI2, and/or the third gate insulating layer GI3 may be etched in a separate patterning process using a mask different from the mask used in the patterning process of a third conductive layer CDL3 that forms the first gate electrode GE1, the second gate electrode GE2, and/or the second electrode CE12. Accordingly, regardless of the shape and/or size of the first gate electrode GE1, the second gate electrode GE2, and/or the second electrode CE12, the first gate insulating layer GI1, the second gate insulating layer GI2, and/or the third gate insulating layer GI3 may be formed in a desired shape and/or size. When the third conductive layer CDL3 and the gate insulating layer GI are etched sequentially (or substantially simultaneously) by using the mask used in the patterning process of the third conductive layer CDL3, a by-product, which may occur as a result of exposure of an end of the pattern (e.g., the first gate electrode GE1, the second gate electrode GE2, and/or the second electrode CE12) of the third conductive layer CDL3 as the mask degenerates, may adhere to the side surface of the pattern (e.g., the first gate insulating layer GI1, the second gate insulating layer GI2, and/or the third gate insulating layer GI3) of the gate insulating layer GI, causing a short circuit defect (e.g., a short circuit defect between the first gate electrode GE1 and the first active layer ACT1). On the other hand, in case that the etching process of the third conductive layer CDL3 and the etching process of the gate insulating layer GI are separated as in the embodiment, the short circuit defect may be prevented. Accordingly, it may be possible to prevent a defect in the display device 100 and improve yield.

In an embodiment, the gate insulating layer GI may be etched in the step of forming a first contact hole CNT1 to be patterned into the first gate insulating layer GI1, the second gate insulating layer GI2, and/or the third gate insulating layer GI3. Accordingly, it may be possible to reduce the manufacturing cost of the display device 100 and increase the manufacturing efficiency thereof. For example, by etching the gate insulating layer GI in the mask process for forming the first contact hole CNT1, the mask process for patterning the third conductive layer CDL3 and the gate insulating layer GI may be separated without adding an additional mask process.

In an embodiment, the first gate insulating layer GI1 may have a larger area than the first gate electrode GE1, and may protrude to the outside of the first gate electrode GE1. For example, the first gate insulating layer GI1 may include a top surface having an area larger than that of the bottom surface of the first gate electrode GE1, and may protrude to the outside of the first gate electrode GE1 in a plan view. In an embodiment, in the lengthwise direction of a first channel region CH1 (e.g., a direction extending from an end of the first channel region CH1 adjacent to a first source region SR1 to another end of the first channel region CH1 adjacent to a first drain region DR1), the first gate electrode GE1 may have a first length L1, and the first gate insulating layer GI1 may have a second length L2 longer than the first length L1.

For example, the first gate insulating layer GI1 may further cover, in addition to a part (e.g., a portion including the first channel region CH1) of the first active layer ACT1 overlapping the first gate electrode GE1, another part (e.g., a portion of the first source region SR1 and a portion of the first drain region DR1 that may be adjacent to the first channel region CH1) of the first active layer ACT1 very near to that part of the first active layer ACT1. Accordingly, the effective channel length of the first transistor TFT1 may be sufficiently secured, and the operating characteristics of the first transistor TFT1 may be improved and/or secured.

In an embodiment, the first gate insulating layer GI1 may not be disposed on the remaining portion (e.g., another part of the first source region SR1 and another part of the first drain region DR1) of the first active layer ACT1, thereby exposing the remaining portion of the first active layer ACT1. The remaining portion of the first active layer ACT1 may be covered by the first insulating layer INS1. Accordingly, the first source region SR1 and the first drain region DR1 may be readily and/or appropriately made conductive.

In an embodiment, the second gate insulating layer GI2 may have an area larger than that of the second electrode CE12 provided in the third conductive layer CDL3, and may protrude to the outside of the second electrode CE12. For example, the second gate insulating layer GI2 may include a top surface having an area larger than that of the bottom surface of the second electrode CE12, and may protrude to the outside of the second electrode CE12 in a plan view.

In an embodiment, the third gate insulating layer GI3 may have a larger area than the second gate electrode GE2, and may protrude to the outside of the second gate electrode GE2. For example, the third gate insulating layer GI3 may include a top surface having an area larger than that of the bottom surface of the second gate electrode GE2, and may protrude to the outside of the second gate electrode GE2 in a plan view. For example, in the lengthwise direction of a second channel region CH2 (or in the lengthwise direction of the second active layer ACT2), the third gate insulating layer GI3 may have a longer length than the second gate electrode GE2.

For example, the third gate insulating layer GI3 may further cover, in addition to a part (e.g., a portion including the second channel region CH2) of the second active layer ACT2 overlapping the second gate electrode GE2, another part (e.g., a portion of a second source region SR2 and a portion of a second drain region DR2 that may be adjacent to the second channel region CH2) of the second active layer ACT2 very near to that part of the second active layer ACT2. Accordingly, the effective channel length of the second transistor TFT2 may be sufficiently secured, and the operating characteristics of the second transistor TFT2 may be improved and/or secured.

In an embodiment, the third gate insulating layer GI3 may not be disposed on the remaining portion (e.g., another part of the second source region SR2 and another part of the second drain region DR2) of the second active layer ACT2, thereby exposing the remaining portion of the second active layer ACT2. The remaining portion of the second active layer ACT2 may be covered by the first insulating layer INS1. Accordingly, the second source region SR2 and the second drain region DR2 may be readily and/or appropriately made conductive.

The first transistor TFT1 may include the first active layer ACT1 (also referred to as “first active pattern” or “first semiconductor pattern”) and the first gate electrode GE1. In an embodiment, the first transistor TFT1 may further include the first bottom gate electrode BG1 (also referred to as “first lower electrode” or “first light blocking pattern”). The buffer layer BFL may be disposed between the first bottom gate electrode BG1 and the first active layer ACT1. The first gate insulating layer GI1 may be disposed between the first active layer ACT1 and the first gate electrode GE1.

In an embodiment, the first transistor TFT1 may further include the first source electrode SE1 and the first drain electrode DE1 electrically connected to different parts of the first active layer ACT1. The first transistor TFT1 may not include an additional source electrode and/or drain electrode, and a first source region SR1 and/or a first drain region DR1 of the first active layer ACT1 may be electrically connected to another circuit element, wire, and/or conductive pattern to function as the source electrode and/or the drain electrode of the first transistor TFT1.

In an embodiment, the first transistor TFT1 may be an N-type transistor. For example, the first transistor TFT1 may be an N-type oxide transistor.

The first bottom gate electrode BG1 may be included or provided in a second conductive layer CDL2 on the substrate SUB. In an embodiment, the second conductive layer CDL2 may be disposed between the barrier layer BRL and the buffer layer BFL. The second conductive layer CDL2 may be covered by the buffer layer BFL.

The first bottom gate electrode BG1 may overlap the first active layer ACT1. For example, the first bottom gate electrode BG1 may be disposed under the first active layer ACT1 to overlap at least a first channel region CH1. By disposing the first bottom gate electrode BG1 under the first active layer ACT1, external light may be prevented from reaching the first active layer ACT1 (e.g., the first channel region CH1), and the operating characteristics of the first transistor TFT1 may be stabilized.

The first bottom gate electrode BG1 and the first active layer ACT1 may be spaced apart from each other with the buffer layer BFL disposed therebetween. The first bottom gate electrode BG1 may face the first gate electrode GE1 with the first active layer ACT1 disposed therebetween.

In an embodiment, the first bottom gate electrode BG1 may be electrically connected to an electrode of the first transistor TFT1. In an embodiment, the first transistor TFT1 may be a driving transistor of the pixel PX, and the first bottom gate electrode BG1 may be electrically connected to the first source electrode SE1. The first transistor TFT1 may be a switching transistor of the pixel PX, and the first bottom gate electrode BG1 may be electrically connected to the first gate electrode GE1. For example, the first bottom gate electrode BG1 may be electrically connected to the first source electrode SE1 or the first gate electrode GE1, and may be used as a back-gate electrode serving to adjust the characteristics of the first transistor TFT1.

The first active layer ACT1 may be included or provided in a semiconductor layer SCL on the substrate SUB. In an embodiment, the semiconductor layer SCL may be disposed on the buffer layer BFL, and may be covered by the gate insulating layer GI and the first insulating layer INS1.

The first active layer ACT1 may include the first channel region CH1 and the first source region SR1 and the first drain region DR1 spaced apart from each other with the first channel region CH1 disposed therebetween. For example, the first source region SR1 and the first drain region DR1 may be located at both sides of the first channel region CH1. The first channel region CH1 may be a region that maintains semiconductor characteristics without becoming conductive. The first source region SR1 and the first drain region DR1, which may be regions that have become conductive, may have a carrier concentration (for example, electron concentration) higher than that of the first channel region CH1.

The first active layer ACT1 may overlap the first bottom gate electrode BG1 and the first gate electrode GE1. For example, a part of the first active layer ACT1 including the first channel region CH1 may overlap the first bottom gate electrode BG1 and the first gate electrode GE1.

In an embodiment, the first active layer ACT1 may include an oxide semiconductor. For example, the first active layer ACT1 may include at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or other oxide semiconductors.

In an embodiment, the first active layer ACT1 may be formed of a high-mobility oxide semiconductor (for example, an oxide semiconductor material with mobility of about 20 cm²/Vs or about 30 cm²/Vs or more). For example, the first active layer ACT1 may be formed of indium-gallium-zinc oxide (IGZO) or indium-tin-gallium-zinc oxide (ITGZO), and may have mobility equal to or larger than about 30 cm²/Vs. In case that the first active layer ACT1 is formed of such an oxide semiconductor having high mobility, the conductivity of the first source region SR1 and the first drain region DR1 may be appropriately and/or readily secured without performing an additional doping process or the like. In case that the first active layer ACT1 is formed of such an oxide semiconductor having high mobility, the mobility of the first transistor TFT1 may be properly secured while forming the first transistor TFT1 into a microscopic size (e.g., a size including an active layer having a width and/or a length in the range of about several micrometers to several tens of micrometers).

The first gate insulating layer GI1 may be disposed on the first active layer ACT1. The first gate insulating layer GI1 may be disposed between the first active layer ACT1 and the first gate electrode GE1.

In an embodiment, the first gate insulating layer GI1 may be disposed only on a portion of the first active layer ACT1 overlapping the first gate electrode GE1, and may not be disposed on another portion of the first active layer ACT1. For example, the first gate insulating layer GI1 may cover a portion of the first active layer ACT1 including the first channel region CH1, while exposing the first source region SR1 and the first drain region DR1. However, embodiments may not be limited thereto. For example, the first gate insulating layer GI1 may be entirely disposed in the display area DA.

Since the first gate insulating layer GI1 exposes the first source region SR1 and the first drain region DR1, the first source region SR1 and the first drain region DR1 may become appropriately and/or readily conductive in the manufacturing process of the display panel 110. For example, oxygen vacancies may occur in the first source region SR1 and the first drain region DR1 due to an etching gas or the like in the step of etching the gate insulating layer GI so that the first source region SR1 and the first drain region DR1 may be exposed. Accordingly, the first source region SR1 and the first drain region DR1 may be appropriately made conductive in a subsequent process (e.g., in a process of forming the first insulating layer INS1) without performing an additional doping process.

In an embodiment, in order to limit the carrier concentration of the first source region SR1 and the first drain region DR1 and/or the mobility of the first active layer ACT1 to an appropriate range, an oxygen supply layer may be formed between the first gate insulating layer GI1 and the first gate electrode GE1. As an example, the first transistor TFT1 may further include an oxygen supply layer including an oxide semiconductor, and the oxygen supply layer may be disposed between the first gate insulating layer GI1 and the first gate electrode GE1. The first active layer ACT1 and the oxygen supply layer of the first transistor TFT1 may include the same oxide semiconductor or different oxide semiconductors.

The first gate electrode GE1 may be included or provided in the third conductive layer CDL3 on the substrate SUB. In an embodiment, the third conductive layer CDL3 may be disposed on the gate insulating layer GI, and may be covered by the first insulating layer INS1. For example, the first gate electrode GE1 may be disposed on the first gate insulating layer GI1 and covered by the first insulating layer INS1.

The first gate electrode GE1 may be disposed on the first active layer ACT1 to overlap the first channel region CH1. The first gate electrode GE1 and the first active layer ACT1 may be separated and/or spaced apart from each other with the first gate insulating layer GI1 disposed therebetween.

The first source electrode SE1 and the first drain electrode DE1 may be included or provided in a fourth conductive layer CDL4 on the substrate SUB. In an embodiment, the fourth conductive layer CDL4 may be disposed on the first insulating layer INS1 entirely covering the buffer layer BFL, the semiconductor layer SCL, the gate insulating layer GI, and the third conductive layer CDL3. The fourth conductive layer CDL4 may be covered by the second insulating layer INS2.

The first source electrode SE1 may be electrically connected to a part of the first active layer ACT1. For example, the first source electrode SE1 may be electrically connected to the first source region SR1 through the second contact hole CNT2 penetrating the first insulating layer INS1. In an embodiment, the first source electrode SE1 may be further electrically connected to the first bottom gate electrode BG1 through a third contact hole CNT3 penetrating the buffer layer BFL and the first insulating layer INS1.

The first drain electrode DE1 may be electrically connected to another part of the first active layer ACT1. For example, the first drain electrode DE1 may be electrically connected to the first drain region DR1 through the fourth contact hole CNT4 penetrating the first insulating layer INS1.

The second transistor TFT2 may include the second active layer ACT2 (also referred to as “second active pattern” or “second semiconductor pattern”) and the second gate electrode GE2. In an embodiment, the second transistor TFT2 may further include the second bottom gate electrode BG2 (also referred to as “second lower electrode” or “second light blocking pattern”). The buffer layer BFL may be disposed between the second bottom gate electrode BG2 and the second active layer ACT2. The third gate insulating layer GI3 may be disposed between the second active layer ACT2 and the second gate electrode GE2.

In an embodiment, the second transistor TFT2 may further include the second source electrode SE2 and the second drain electrode DE2 electrically connected to different parts of the second active layer ACT2. The second transistor TFT2 may not include an additional source electrode and/or drain electrode, and the second source region SR2 and/or the second drain region DR2 of the second active layer ACT2 may be electrically connected to another circuit element, wire, and/or conductive pattern to function as the source electrode and/or the drain electrode of the second transistor TFT2.

In an embodiment, the second transistor TFT2 may be an N-type transistor. For example, the second transistor TFT2 may be an N-type oxide transistor.

The second bottom gate electrode BG2 may be included or provided in the second conductive layer CDL2 on the substrate SUB. For example, the second bottom gate electrode BG2 may be included or provided in the second conductive layer CDL2 together with the first bottom gate electrode BG1.

The second bottom gate electrode BG2 may overlap the second active layer ACT2. For example, the second bottom gate electrode BG2 may be disposed under the second active layer ACT2 to overlap at least the second channel region CH2. By disposing the second bottom gate electrode BG2 under the second active layer ACT2, external light may be prevented from reaching the second active layer ACT2 (e.g., the second channel region CH2), and the operating characteristics of the second transistor TFT2 may be stabilized.

The second bottom gate electrode BG2 and the second active layer ACT2 may be spaced apart from each other with the buffer layer BFL disposed therebetween. The second bottom gate electrode BG2 may face the second gate electrode GE2 with the second active layer ACT2 disposed therebetween.

In an embodiment, the second bottom gate electrode BG2 may be electrically connected to an electrode of the second transistor TFT2. In a configuration, the second transistor TFT2 may be a buffer transistor (e.g., a pull-up or pull-down transistor) provided at an output terminal of the first driver 120 or a switching transistor other than the buffer transistor, and the second bottom gate electrode BG2 may be electrically connected to the second gate electrode GE2. For example, the second bottom gate electrode BG2 may be electrically connected to the second gate electrode GE2, and may be utilized as a back-gate electrode that adjusts the characteristics of the second transistor TFT2.

The second active layer ACT2 may be included or provided in the semiconductor layer SCL on the substrate SUB. For example, the second active layer ACT2 may be disposed on the buffer layer BFL and may be covered by the third gate insulating layer GI3 and the first insulating layer INS1.

The second active layer ACT2 may include the second channel region CH2 and the second source region SR2 and the second drain region DR2 spaced apart from each other with the second channel region CH2 disposed therebetween. For example, the second source region SR2 and the second drain region DR2 may be located at both sides of the second channel region CH2. The second channel region CH2 may be a region that maintains semiconductor characteristics without becoming conductive. The second source region SR2 and the second drain region DR2, which may be regions that have become conductive, may have a carrier concentration (for example, electron concentration) higher than that of the second channel region CH2.

The second active layer ACT2 may overlap the second bottom gate electrode BG2 and the second gate electrode GE2. For example, a part of the second active layer ACT2 including the second channel region CH2 may overlap the second bottom gate electrode BG2 and the second gate electrode GE2.

In an embodiment, the second active layer ACT2 may include an oxide semiconductor. For example, the second active layer ACT2 may include the oxide semiconductor exemplified above as the material of the first active layer ACT1, or another oxide semiconductor. In an embodiment, the first active layer ACT1 and the second active layer ACT2 may include the same oxide semiconductor. For example, the first active layer ACT1 and the second active layer ACT2 may be formed simultaneously on the buffer layer BFL using the same oxide semiconductor. Accordingly, the manufacturing process of the display panel 110 may be simplified and/or streamlined, and the manufacturing efficiency may be increased.

The third gate insulating layer GI3 may be disposed on the second active layer ACT2. The third gate insulating layer GI3 may be disposed between the second active layer ACT2 and the second gate electrode GE2.

In an embodiment, the third gate insulating layer GI3 may be disposed only on a portion of the second active layer ACT2 overlapping the second gate electrode GE2, and may not be disposed on another portion of the second active layer ACT2. For example, the third gate insulating layer GI3 may cover a portion of the second active layer ACT2 including the second channel region CH2, while exposing the second source region SR2 and the second drain region DR2. However, embodiments may not be limited thereto. For example, the third gate insulating layer GI3 may entirely cover the active layer provided in at least one driver transistor Tdr.

Since the third gate insulating layer GI3 exposes the second source region SR2 and the second drain region DR2, the second source region SR2 and the second drain region DR2 may become appropriately and/or readily conductive in the manufacturing process of the display panel 110. For example, oxygen vacancies may occur in the second source region SR2 and the second drain region DR2 due to an etching gas or the like in the step of etching the gate insulating layer GI so that the second source region SR2 and the second drain region DR2 may be exposed. Accordingly, the second source region SR2 and the second drain region DR2 may be appropriately made conductive in a subsequent process without performing an additional doping process.

The second gate electrode GE2 may be included or provided in the third conductive layer CDL3. For example, the second gate electrode GE2 may be disposed on the gate insulating layer GI (e.g., the third gate insulating layer GI3), and may be covered by the second insulating layer INS2.

The second gate electrode GE2 may be disposed on a part of the second active layer ACT2 to overlap the second channel region CH2. The second gate electrode GE2 and the second active layer ACT2 may be separated and/or spaced apart from each other with the third gate insulating layer GI3 disposed therebetween.

The second source electrode SE2 and the second drain electrode DE2 may be included or provided in the fourth conductive layer CDL4. For example, the second source electrode SE2 and the second drain electrode DE2 may be disposed on the first insulating layer INS1 and may be covered by the second insulating layer INS2.

The second source electrode SE2 may be electrically connected to a part of the second active layer ACT2. For example, the second source electrode SE2 may be electrically connected to the second source region SR2 through the fifth contact hole CNT5 penetrating the first insulating layer INS1.

The second drain electrode DE2 may be electrically connected to another part of the second active layer ACT2. For example, the second drain electrode DE2 may be electrically connected to the second drain region DR2 through the sixth contact hole CNT6 penetrating the first insulating layer INS1.

The first capacitor electrode CEI may be a multi-layer electrode including a first electrode CE11 and the second electrode CE12 included or provided in different conductive layers. As an example, the first electrode CE11 may be a first sub-electrode (or lower electrode layer) of the first capacitor electrode CE1 included or provided in a first conductive layer CDL1, and the second electrode CE12 may be a second sub-electrode (or upper electrode layer) of the first capacitor electrode CE1 included or provided in the third conductive layer CDL3 and electrically connected to the first electrode CE11. The first electrode CE11 and the second electrode CE12 may be electrically connected to each other through the first contact hole CNT1 penetrating the barrier layer BRL, the buffer layer BFL, and the gate insulating layer GI (e.g., the second gate insulating layer GI2) disposed between the first conductive layer CDLI and the third conductive layer CDL3. However, embodiments may not be limited thereto. For example, in case that the display panel 110 does not include the first conductive layer CDLI, the first electrode CE11 may be included or provided in a conductive layer (e.g., the second conductive layer CDL2) on the barrier layer BRL, and the first electrode CE11 and the second electrode CE12 may be electrically connected to each other through a contact hole penetrating the buffer layer BFL and the gate insulating layer GI.

In an embodiment, the second electrode CE12 may be electrically connected to the first gate electrode GE1. As an example, the second electrode CE12 and the first gate electrode GE1 may be provided in the third conductive layer CDL3 to be electrically connected to each other in a plan view and may be integral with each other.

In an embodiment, the display panel 110 may further include at least one wire including multiple sub-wires (or sub-wiring layers) included or provided in different conductive layers, having a structure similar to that of the first capacitor electrode CE1. For example, the display panel 110 may further include a multilayer wire including sub-wires included or provided in the first conductive layer CDL1, the second conductive layer CDL2, and/or the third conductive layer CDL3.

Circuit elements and electrodes of the display area DA including the first transistor TFT1 and the first capacitor electrode CEI, circuit elements of the driving circuit area DRA including the second transistor TFT2, and wires electrically connected to the pixels PX and/or the first driver 120 may be covered by the second insulating layer INS2.

The respective electrodes, conductive patterns, and/or wires included or provided in the conductive layers of the pixel circuit layer PCL may include at least one conductive material. For example, the electrodes, the conductive patterns, and/or the wires included or provided in each of the first conductive layer CDL1, the second conductive layer CDL2, the third conductive layer CDL3, and the fourth conductive layer CDL4 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or another metal, an alloy thereof, or another conductive material. In an embodiment, the electrodes, the conductive patterns, and/or the wires included or provided in the same conductive layer may be simultaneously formed using the same conductive material.

In an embodiment, each of the electrodes, conductive patterns, and/or wires included or provided in the conductive layers of the panel circuit layer PCL may have a single-layer or multi-layer structure. For example, each of the electrodes, conductive patterns, and/or wires included or provided in the first conductive layer CDLI, the second conductive layer CDL2, the third conductive layer CDL3, and the fourth conductive layer CDL4 may have a single-layer or multiple-layer structure.

The second insulating layer INS2 may be disposed on the fourth conductive layer CDL4. For example, the second insulating layer INS2 may be disposed on the first insulating layer INS1, and may cover the fourth conductive layer CDL4.

In an embodiment, the second insulating layer INS2 may have a multi-layer structure including an inorganic insulating layer and an organic insulating layer. For example, the second insulating layer INS2 may include an inorganic layer IOL and an organic layer ORL sequentially disposed on the first insulating layer INS1.

In an embodiment, each of the barrier layer BRL, the buffer layer BFL, the gate insulating layer GI, the first insulating layer INS1, and the inorganic layer IOL may include at least one inorganic insulating layer containing an inorganic insulating material (e.g., silicon nitride, silicon oxide, silicon oxynitride, titanium oxide, aluminum oxide, another inorganic insulating material, or a combination thereof). For example, each of the barrier layer BRL, the buffer layer BFL, the gate insulating layer GI, the first insulating layer INS1, and the inorganic layer IOL may be a single-layer or multi-layer inorganic insulating layer.

In an embodiment, the organic layer ORL may include at least one organic insulating layer containing an organic insulating material (e.g., acryl resin, epoxy resin, phenolic resin, polyamide resin, polyimide resin, other organic insulating materials, or a combination thereof). The surface (for example, the top surface) of the organic layer ORL may be approximately flat.

The light emitting element layer LEL may be disposed on the panel circuit layer PCL. For example, the light emitting element layer LEL may be positioned at least in the display area DA, and may be disposed on the second insulating layer INS2.

The light emitting element layer LEL may include the light emitting elements ED of the pixels PX. For example, the light emitting element layer LEL may include a pixel defining layer PDL (also referred to as “bank”) that partitions the emission areas of the pixels PX and the light emitting element ED located in each emission area. In an embodiment, the light emitting element layer LEL may further include a spacer SPC disposed on a part of the pixel defining layer PDL.

Each light emitting element ED may include a first electrode ET1 located in each emission area, and a light emitting layer EML and a second electrode ET2 sequentially disposed on the first electrode ET1. The first electrode ET1 of the light emitting element ED may be electrically connected to at least one pixel transistor Tpx (e.g., the first transistor TFT1) included in the corresponding pixel PX.

The first electrode ET1 of the light emitting element ED may be a single-layer or multi-layer electrode including at least one conductive material. In an embodiment, the first electrode ET1 may include a metallic material having high reflectivity. For example, the first electrode ET1 may have a single-layer structure of molybdenum (Mo), titanium (Ti), copper (Cu), aluminum (Al), or a combination thereof, or may have a multi-layer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), nickel (Ni), or a combination thereof.

The light emitting layer EML of the light emitting element ED may include a high molecular material or a low molecular material. Light emitted from the light emitting layer EML may contribute to image display.

The second electrode ET2 of the light emitting element ED may include a conductive material. In an embodiment, the second electrode ET2 may be a common layer formed across the entire display area DA to cover the light emitting layer EML and the pixel defining layer PDL. In an embodiment, the second electrode ET2 may be formed of a transparent conductive material such as ITO, IZO, ZnO, ITZO, the like, or a combination thereof capable of transmitting light, or a semi-transmissive conductive material such as magnesium (Mg), silver (Ag), an alloy of magnesium (Mg) and silver (Ag), or a combination thereof.

The pixel defining layer PDL may have an opening corresponding to each emission area and may surround the emission area. For example, the pixel defining layer PDL may be formed to cover an edge of the first electrode ET1 of the light emitting element ED and may include an opening exposing the remaining portion of the first electrode ET1. In an embodiment, the pixel defining layer PDL may include at least one organic insulating layer containing an organic insulating material.

The spacer SPC may be disposed on a part of the pixel defining layer PDL. The spacer SPC may include at least one organic insulating layer containing an organic insulating material. The spacer SPC and the pixel defining layer PDL may include a same material or different materials. The pixel defining layer PDL and the spacer SPC may be sequentially formed through individual mask processes, or may be simultaneously formed and/or integral with each other using a halftone mask.

The encapsulation layer ENL may be disposed on the light emitting element layer LEL. The encapsulation layer ENL may cover the light emitting element layer LEL in the display area DA and may extend to the non-display area NDA to be in contact with the panel circuit layer PCL. The encapsulation layer ENL may block the permeation of oxygen or moisture into the light emitting element layer LEL, and may reduce electrical and/or physical impacts to the panel circuit layer PCL and the light emitting element layer LEL.

In an embodiment, the encapsulation layer ENL may include a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer containing an inorganic material. The second encapsulation layer ENL2 may be an organic encapsulation layer containing an organic material.

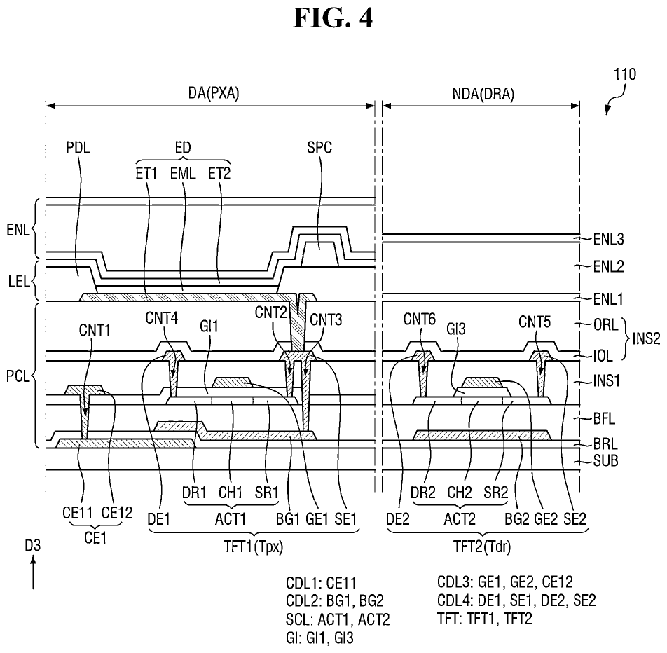

FIG. 4 is a schematic cross-sectional view illustrating the display panel 110 according to an embodiment. For example, FIG. 4 shows an embodiment different from the embodiment of FIG. 3 in relation to the first gate insulating layer GI1.

Referring to FIG. 4 in addition to FIGS. 1 to 3, the first gate insulating layer GI1 may entirely cover the first active layer ACT1. For example, the first gate insulating layer GI1 may entirely cover the first active layer ACT1 except for a region where contact holes (e.g., the second contact hole CNT2 and the fourth contact hole CNT4) for connecting the first source region SR1 and the first drain region DR1 to the first source electrode SE1 and the first drain electrode DE1, respectively, as well as to the first active layer ACT1 may be formed.

In an embodiment, the first gate insulating layer GI1 and the second gate insulating layer GI2 of FIG. 3 may be integral with each other. For example, the first gate insulating layer GI1 and the second gate insulating layer GI2 may be combined into one first gate insulating layer GI1 as shown in FIG. 4. As an example, the first gate insulating layer GI1 may be formed across each pixel area PXA and/or the display area DA.

In an embodiment, by etching the gate insulating layer GI in the step of forming the first contact hole CNT1, the gate insulating layer GI disposed in each transistor area of the pixel area PXA and/or the driving circuit area DRA may be differentially and/or selectively etched as required without adding an additional mask process. For example, the first gate insulating layer GI1 may be formed on the active layer (e.g., the first active layer ACT1) of at least one pixel transistor Tpx provided in each pixel area PXA to entirely cover the active layer, and the third gate insulating layer GI3 may be formed on the active layer (e.g., the second active layer ACT2) of at least one driving transistor Tdr provided in the driving circuit area DRA to expose another part of the active layer.

In the same way, the gate insulating layer GI may be differentially and/or selectively etched for the pixel transistors Tpx disposed in the respective pixel areas PXA. For example, for some of the pixel transistors Tpx, each active layer may be entirely covered with the gate insulating layer GI, and for others, the gate insulating layer GI may be partially disposed on each active layer.

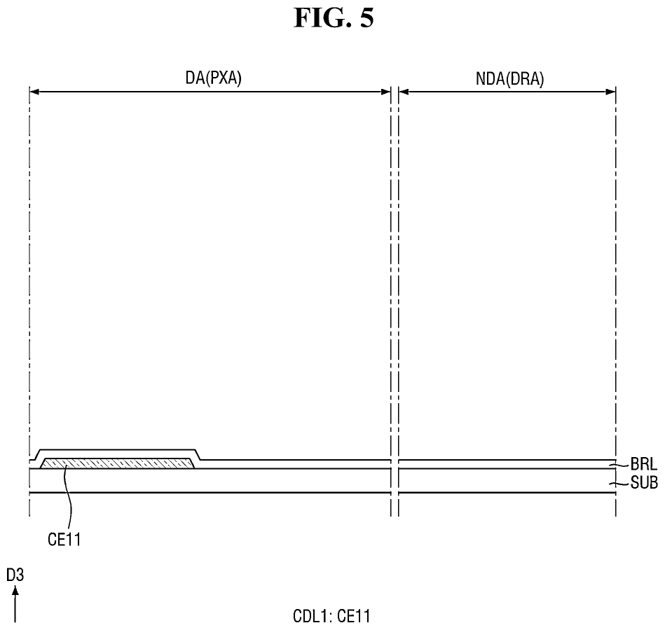

FIGS. 5 to 12 are schematic cross-sectional views showing a method for manufacturing the display device 100 according to an embodiment. For example, FIGS. 5 to 12 sequentially show, among the steps for forming the display panel 110 of FIG. 3, the steps of forming the first capacitor electrode CEI and the first and second transistors TFT1 and TFT2 on the substrate SUB.

Referring to FIG. 5 in addition to FIGS. 1 to 4, the substrate SUB including the display area DA and the non-display area NDA may be prepared. In an embodiment, the display area DA defined on the substrate SUB may include the pixel area PXA, and the non-display area NDA may include the driving circuit area DRA.

Thereafter, the first conductive layer CDLI including the first electrode CE11 may be formed on the substrate SUB. For example, the first electrode CE11 may be formed in each pixel area PXA of the display area DA on the substrate SUB.

The first electrode CE11 may be formed through a film forming process (e.g., a deposition process) of forming a conductive film by using at least one conductive material mentioned above and a patterning process (e.g., an etching process using a mask) of patterning the conductive film.

Thereafter, the barrier layer BRL may be formed on the substrate SUB to cover the first conductive layer CDL1. The barrier layer BRL may be formed in the display area DA and the non-display area NDA. The barrier layer BRL may be formed by an insulating film forming process (for example, a deposition process) using at least one insulating material (for example, an inorganic insulating material) exemplified above.

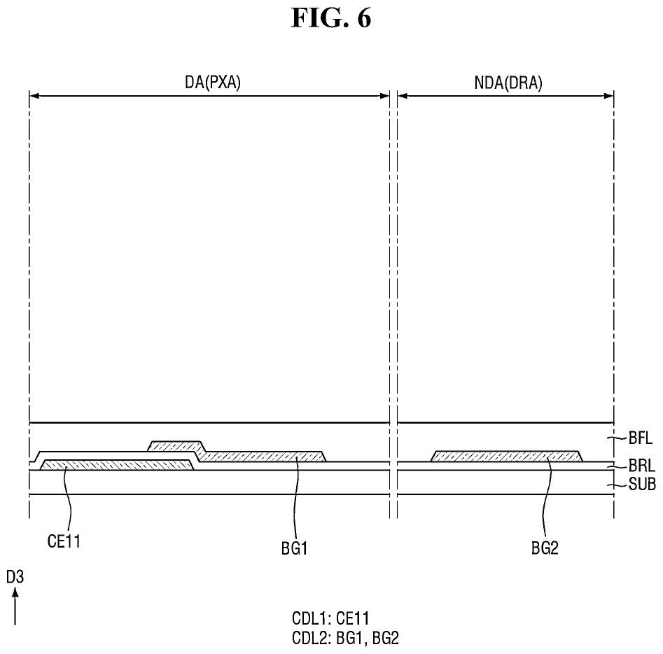

Referring to FIG. 6 in addition to FIGS. 1 to 5, the second conductive layer CDL2 including the first bottom gate electrode BG1 and the second bottom gate electrode BG2 may be formed on the barrier layer BRL. For example, on the substrate SUB, the first bottom gate electrode BG1 may be formed in each pixel area PXA of the display area DA, and the second bottom gate electrode BG2 may be formed in the driving circuit area DRA. The first bottom gate electrode BG1 and the second bottom gate electrode BG2 may be formed by a film forming process (for example, a deposition process) of a conductive film using at least one conductive material exemplified above and a patterning process (for example, an etching process using a mask) of the conductive film.

Thereafter, the buffer layer BFL may be formed on the barrier layer BRL to cover the second conductive layer CDL2. The buffer layer BFL may be formed by a film forming process of an insulating film using at least one insulating material (for example, an inorganic insulating material) exemplified above.

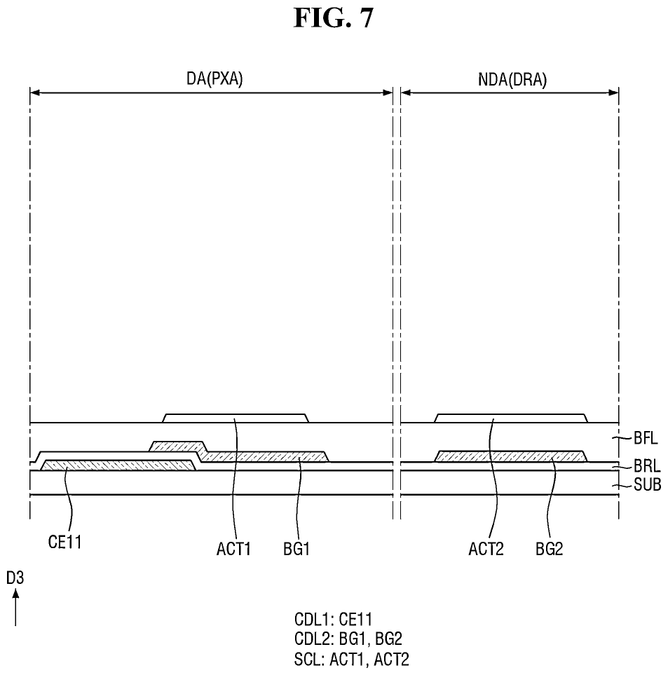

Referring to FIG. 7 in addition to FIGS. 1 to 6, the semiconductor layer SCL including the first active layer ACT1 and the second active layer ACT2 may be formed on the buffer layer BFL. For example, on the substrate SUB, the first active layer ACT1 may be formed in each pixel area PXA of the display area DA, and the second active layer ACT2 may be formed in the driving circuit area DRA. The first active layer ACT1 may be formed to overlap the first bottom gate electrode BG1, and the second active layer ACT2 may be formed to overlap the second bottom gate electrode BG2.

In an embodiment, the first active layer ACT1 and the second active layer ACT2 may be formed simultaneously using the same oxide semiconductor. For example, the first active layer ACT1 and the second active layer ACT2 may be formed in the display area DA and the driving circuit area DRA, respectively, by a film forming process of a semiconductor layer using at least one oxide semiconductor exemplified above and a patterning process.

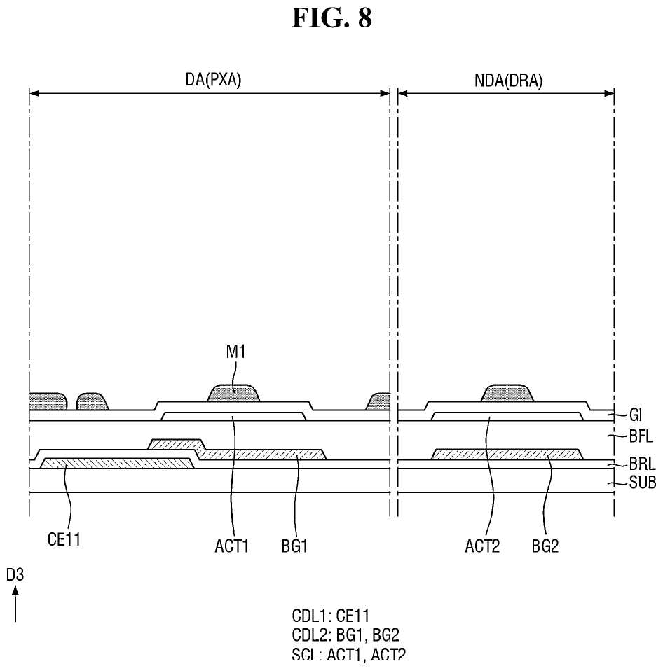

Referring to FIG. 8 in addition to FIGS. 1 to 7, the gate insulating layer GI covering the semiconductor layer SCL may be formed on the buffer layer BFL. The gate insulating layer GI may be first formed on the entire surface of the substrate SUB including the display area DA and the driving circuit area DRA. For example, the gate insulating layer GI may be formed on the buffer layer BFL and the semiconductor layer SCL through an insulating film forming process using at least one insulating material (for example, an inorganic insulating material such as silicon oxide) mentioned above.

Thereafter, a first mask M1 (e.g., a photoresist pattern) may be disposed on the gate insulating layer GI. The first mask M1 may be disposed at a position corresponding to each insulating pattern to be provided in the gate insulating layer GI, including the first gate insulating layer GI1, the second gate insulating layer GI2, and the third gate insulating layer GI3. For example, in each pixel area PXA of the display area DA, the first mask M1 overlapping a part of the first active layer ACT1 and a part of the first electrode CE11 may be disposed on the gate insulating layer GI. The first mask M1 may not be disposed on other portions (e.g., portions in which the first source region SR1 and the first drain region DR1 may be to be formed) of the first active layer ACT1 and another part (e.g., a portion in which the first contact hole CNG1 may be to be formed) of the first electrode CE11. In the driving circuit area DRA, the first mask M1 overlapping a part of the second active layer ACT2 may be disposed on the gate insulating layer GI. The first mask M1 may not be disposed on other portions (e.g., portions in which the second source region SR2 and the second drain region DR2 may be formed) of the second active layer ACT2.

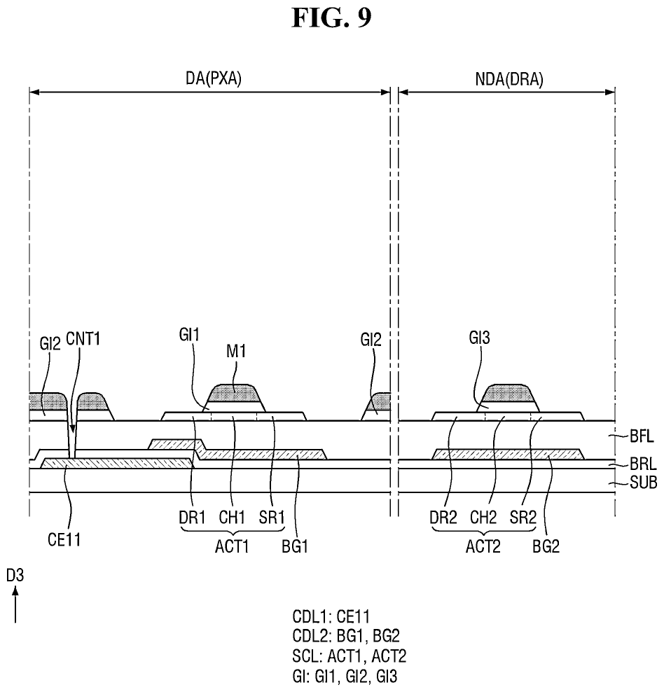

Referring to FIG. 9 in addition to FIGS. 1 to 8, using the first mask M1, the gate insulating layer GI may be etched and the first contact hole CNT1 may be formed using the first mask M1. For example, by etching the gate insulating layer GI to expose another part of the first active layer ACT1 that may not be covered by the first mask M1, the first gate insulating layer GI1 may be formed on a portion of the first active layer ACT1 positioned below the first mask M1. In the same way, the third gate insulating layer GI3 may be formed on a portion of the second active layer ACT2 positioned below the first mask M1. Furthermore, by etching the gate insulating layer GI, the buffer layer BFL, and the barrier layer BRL to expose another part of the first electrode CE11 that may not be covered by the first mask M1, the first contact hole CNT1 may be formed on the first electrode CE11. For example, the first contact hole CNT1 may be formed on the first electrode CE11 to penetrate the gate insulating layer GI, the buffer layer BFL, and the barrier layer BRL. The periphery of the first contact hole CNT1 may be covered by the first mask M1, and, accordingly, the second gate insulating layer GI2 may be formed on the buffer layer BFL around the first contact hole CNT1. By way of example, the second gate insulating layer GI2 may be formed on a part of the first electrode CE11. In the same way, the second gate insulating layer GI2 may also be formed on another part of the pixel area PXA covered by the first mask M1. In an embodiment, the process of etching the gate insulating layer GI and the process of forming the first contact hole CNT1 may be carried out substantially at the same time through a single mask process using the first mask M1. After etching the gate insulating layer GI and forming the first contact hole CNT1, the first mask M1 may be removed.

In the process of etching the gate insulating layer GI, the properties of the first and second active layers ACT1 and ACT2 may be changed such that each of the first and second active layers ACT1 and ACT2 has different characteristics at different portions thereof. Accordingly, each of the first and second active layers ACT1 and ACT2 may be divided into multiple regions having different characteristics.

For example, oxygen vacancies may occur in the first active layer ACT1 due to an etching gas or the like, at a portion where the first mask M1 may not be disposed. Accordingly, the first active layer ACT1 may be divided into multiple regions (for example, the first channel region CH1, the first source region SR1, and the first drain region DR1) having different characteristics. In an embodiment, oxygen vacancies may occur at a portion (for example, the first source region SR1 and the first drain region DR1) of the first active layer ACT1 that does not overlap the first gate insulating layer GI1, and may diffuse to a part of the region that overlaps the first gate insulating layer GI1.

Similarly, at a portion that does not overlap the third gate insulating layer GI3, oxygen vacancies may occur in the second active layer ACT2. Accordingly, the second active layer ACT2 may be divided into multiple regions (for example, the second channel region CH2, the second source region SR2, and the second drain region DR2) having different characteristics. In an embodiment, oxygen vacancies may occur at a portion (for example, the second source region SR2 and the second drain region DR2) of the second active layer ACT2 that does not overlap the third gate insulating layer GI3, and may diffuse to a portion of the region that overlaps the third gate insulating layer GI3.

In embodiments, the first gate insulating layer GI1 and the third gate insulating layer GI3 may be formed to have a larger area than the first gate electrode GE1 and the second gate electrode GE2, respectively to be formed in a subsequent process. For example, the first gate insulating layer GI1 and the third gate insulating layer GI3 may be formed to have longer lengths than the first gate electrode GE1 and the second gate electrode GE2, respectively, in the lengthwise direction (or in the lengthwise direction of the first channel region CH1 and the second channel region CH2) of the first active layer ACT1 and the second active layer ACT2, respectively. For example, the first gate insulating layer GI1 and the third gate insulating layer GI3 may cover a wider portion of each of the first source region SR1, the first drain region DR1, the second source region SR2, and the second drain region DR2 adjacent to the first channel region CH1 and the second channel region CH2, respectively. Accordingly, the length and/or area of the regions in which the first source region SR1, the first drain region DR1, the second source region SR2, and the second drain region DR2 extend in the first active layer ACT1 and the second active layer ACT2, respectively may be reduced, and the effective channel lengths of the first channel region CH1 and the second channel region CH2 may be sufficiently secured. As a result, the operating characteristics of the first transistor TFT1 and the second transistor TFT2 may be improved and/or secured.

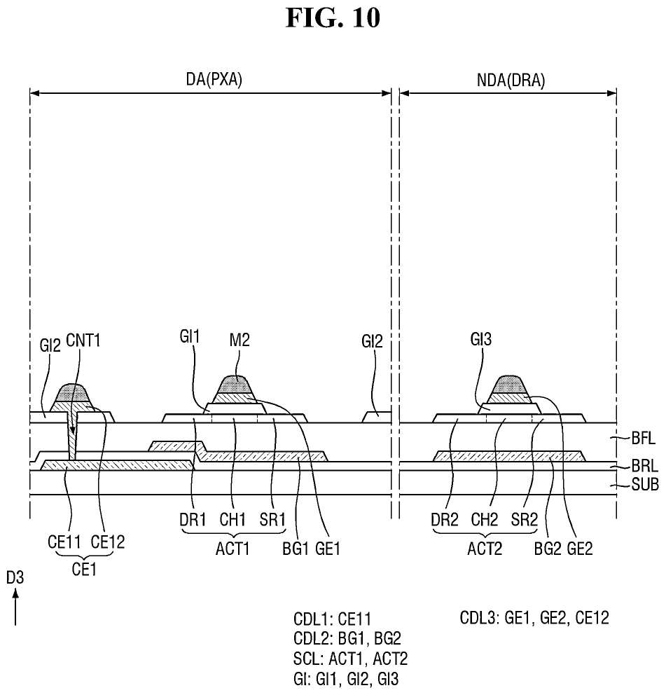

Referring to FIG. 10 in addition to FIGS. 1 to 9, the third conductive layer CDL3 including the second electrode CE12 and the first and second gate electrodes GE1 and GE2 may be formed on the gate insulating layer GI. For example, the first gate electrode GE1, the second electrode CE12, and the second gate electrode GE2 may be formed on the first gate insulating layer GI1, the second gate insulating layer GI2, and the third gate insulating layer GI3, respectively. In an embodiment, the first gate electrode GE1 and the second gate electrode GE2 may be formed on a part of the first gate insulating layer GI1 and a part of the third gate insulating layer GI3, respectively. For example, the first gate electrode GE1 and the second gate electrode GE2 may be formed on a part of the first active layer ACT1 and a part of the second active layer ACT2 to overlap the first channel region CH1 and the second channel region CH2, respectively. In an embodiment, the second electrode CE12 may be formed on a part of the second gate insulating layer GI2. The second electrode CE12 may be electrically connected to the first electrode CE11 through the first contact hole CNT1.

The second electrode CE12 and the first and second gate electrodes GE1 and GE2 may be formed through a film forming process (e.g., a deposition process) of forming a conductive film using at least one conductive material mentioned above and a patterning process of patterning the conductive film. For example, after forming the conductive film on the substrate SUB on which the gate insulating layer GI or the like may be disposed, the second mask M2 may be disposed on the conductive film. Thereafter, by performing an etching process of the conductive film using the second mask M2, the second electrode CE12 and the first and second gate electrodes GE1 and GE2 may be formed. In an embodiment, the second electrode CE12 and the first gate electrode GE1 may be formed as substantially one and of the same electrode. After the etching of the conductive film for forming the third conductive layer CDL3, the second mask M2 may be removed.

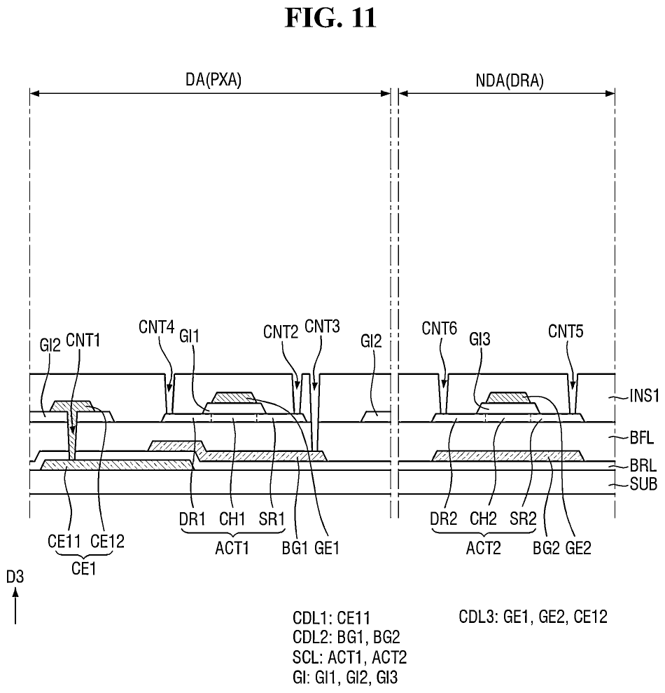

Referring to FIG. 11 in addition to FIGS. 1 to 10, the first insulating layer INS1 covering the semiconductor layer SCL, the gate insulating layer GI, and the third conductive layer CDL3 may be formed on the buffer layer BFL. For example, the first insulating layer INS1 may be formed on the third conductive layer CDL3 to cover the first and second active layers ACT1 and ACT2, the first, second and third gate insulating layers GI1, GI2, and GI3, the first and second gate electrodes GE1 and GE2, and the second electrode CE12. The first insulating layer INS1 may be formed entirely in the display area DA and the non-display area NDA (for example, the driving circuit area DRA). The first insulating layer INS1 may be formed by a film forming process of an insulating film using at least one insulating material (for example, an inorganic insulating material) exemplified above.

In the process of forming the first insulating layer INS1, hydrogen may flow into the first active layer ACT1 and the second active layer ACT2. In an embodiment, a heat treatment process (for example, annealing) may be additionally performed on the first active layer ACT1 and the second active layer ACT2 before or after the formation of the first insulating layer INS1. Even in the heat treatment process, hydrogen may flow into the first active layer ACT1 and the second active layer ACT2.

As hydrogen may be introduced into the first active layer ACT1 and the second active layer ACT2, at the portion containing a large number of oxygen vacancies, the first active layer ACT1 and the second active layer ACT2 may partially become conductive (e.g., N type). For example, the first source region SR1, the first drain region DR1, the second source region SR2, and the second drain region DR2 may become conductive.

Thereafter, multiple contact holes may be formed in the first insulating layer INS1. For example, the second, fourth, fifth, and sixth contact holes CNT2, CNT4, CNT5, and CNT6 penetrating the first insulating layer INS1 and exposing a part of each of the first active layer ACT1 and the second active layer ACT2 may be formed. In an embodiment, in case that the first bottom gate electrode BG1 is electrically connected to the first source electrode SE1, the third contact hole CNT3 penetrating the first insulating layer INS1 and the buffer layer BFL and exposing a part of the first bottom gate electrode BG1 may be further formed.

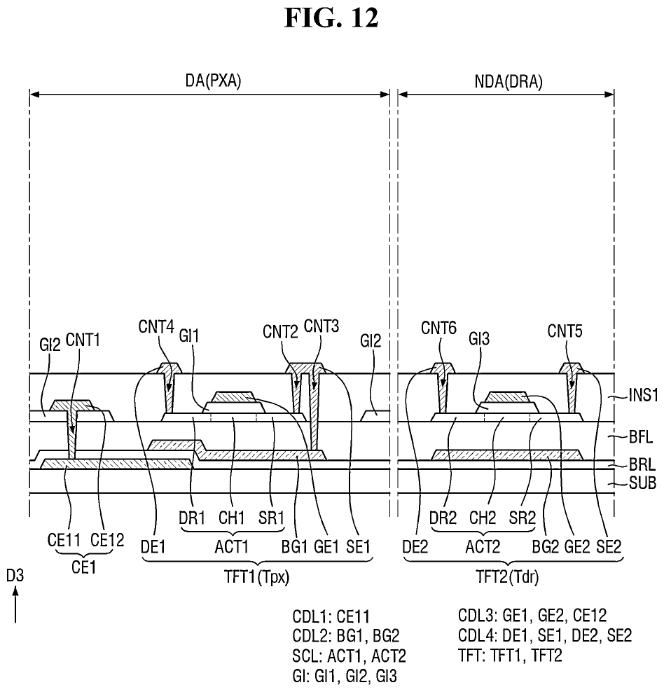

Referring to FIG. 12 in addition to FIGS. 1 to 11, the fourth conductive layer CDL4 including the first source electrode SE1, the first drain electrode DE1, the second source electrode SE2, and the second drain electrode DE2 may be formed on the first insulating layer INS1. In an embodiment, at least one of the first source region SR1, the first drain region DR1, the second source region SR2, or the second drain region DR2 replaces at least one of the first source electrode SE1, the first drain electrode DE1, the second source electrode SE2, or the second drain electrode DE2, at least one of the first source electrode SE1, the first drain electrode DE1, the second source electrode SE2, or the second drain electrode DE2 may not be formed.

By the above-described process, multiple transistors TFT including the first transistor TFT1 and the second transistor TFT2 and multiple capacitor electrodes including the first capacitor electrode CE1 may be formed in the display area DA and the driving circuit area DRA. Multiple wires may be further formed in the conductive layers of the panel circuit layer PCL. In an embodiment, elements provided in the same conductive layer or the same semiconductor layer in the display panel 110 may be formed simultaneously.

After forming the transistors TFT, the capacitor electrodes, and/or the wires, a process of forming the second insulating layer INS2 shown in FIG. 3 may be performed. For example, the second insulating layer INS2 may cover the transistors TFT, the capacitor electrodes, and/or the wires. Accordingly, the panel circuit layer PCL of the display panel 110 may be formed.

In an embodiment, in case that the display panel 110 includes the light emitting element layer LEL and the encapsulation layer ENL disposed on the panel circuit layer PCL, the light emitting element layer LEL and the encapsulation layer ENL may be sequentially formed on the panel circuit layer PCL. Through the above-described processes, the display panel 110 and the display device 100 including the same according to the embodiments may be manufactured.

In concluding the detailed description, those skilled in the art will appreciate that many variations and modifications can be made to the embodiments without substantially departing from the principles of the disclosure. Therefore, the disclosed embodiments of the disclosure may be used in a generic and descriptive sense only and not for purposes of limitation.

What is claimed is:

1. A display device comprising:
a first electrode disposed on a substrate;
a buffer layer disposed on the first electrode;
a first transistor comprising a first active layer disposed on the buffer layer and a first gate electrode disposed on a part of the first active layer;
a second electrode disposed on the buffer layer, and electrically connected to the first electrode;
a first gate insulating layer disposed between the first active layer and the first gate electrode, wherein in a plan view
an area of a top surface of the first gate insulating layer is larger than an area of a bottom surface of the first gate electrode, and
the first gate insulating layer protrudes to an outside of the first gate electrode; and
a second gate insulating layer disposed between the buffer layer and the second electrode, the second gate insulating layer and the first gate insulating layer including a same material.

2. The display device of claim 1, wherein in a plan view
the first active layer comprises a channel region overlapping the first gate electrode, and a source region and a drain region located at both sides of the channel region, and
in a lengthwise direction of the channel region, the first gate electrode has a first length, and the first gate insulating layer has a second length longer than the first length.

3. The display device of claim 1, wherein in a plan view, the first gate insulating layer overlaps only a part of the first active layer and exposes another part of the first active layer.

4. The display device of claim 3, wherein the first gate insulating layer and the second gate insulating layer are separated from each other.

5. The display device of claim 1, further comprising:
a second transistor comprising a second active layer disposed on the buffer layer and a second gate electrode disposed on a part of the second active layer; and
a third gate insulating layer disposed between the second active layer and the second gate electrode, wherein in a plan view
an area of a top surface of the third gate insulating layer is larger than an area of a bottom surface of the second gate electrode, and
the third gate insulating layer protrudes to an outside of the second gate electrode.

6. The display device of claim 5, wherein
the third gate insulating layer and the first gate insulating layer include a same material, and
the third gate insulating layer is separated from the first gate insulating layer.

7. The display device of claim 5, wherein in a plan view
the first gate insulating layer overlaps only a part of the first active layer and exposes another part of the first active layer, and
the third gate insulating layer overlaps only a part of the second active layer and exposes another part of the second active layer.

8. The display device of claim 5, wherein in a plan view
the first gate insulating layer entirely covers the first active layer, and
the third gate insulating layer overlaps only a part of the second active layer and exposes another part of the second active layer.

9. The display device of claim 8, wherein the first gate insulating layer and the second gate insulating layer are integral with each other.

10. The display device of claim 5, wherein the first active layer and the second active layer include a same oxide semiconductor.

11. The display device of claim 1, further comprising:
a barrier layer disposed between the first electrode and the buffer layer, the barrier layer covering the first electrode in a plan view; and
a bottom gate electrode disposed between the barrier layer and the buffer layer, the bottom gate electrode overlaps the first active layer in a plan view.

12. The display device of claim 11, wherein the second electrode is electrically connected to the first electrode through a contact hole penetrating the barrier layer, the buffer layer, and the second gate insulating layer.

13. The display device of claim 11, wherein
the bottom gate electrode faces the first gate electrode with the first active layer disposed therebetween, and
the bottom gate electrode is electrically connected to an electrode of the first transistor.

14. The display device of claim 1, further comprising:
a first insulating layer disposed on the buffer layer and covering the first active layer, the first gate insulating layer, the second gate insulating layer, the first gate electrode, and the second electrode.

15. The display device of claim 14, wherein the first transistor further comprises at least one of:
a source electrode disposed on the first insulating layer and electrically connected to a part of the first active layer; or
a drain electrode disposed on the first insulating layer and electrically connected to another part of the first active layer.

16. The display device of claim 14, further comprising:
a second insulating layer disposed on the first insulating layer and covering the first transistor;
a light emitting element layer comprising a light emitting element disposed on the second insulating layer; and
an encapsulation layer covering the light emitting element layer.

17. A method for manufacturing a display device, comprising:
forming a first electrode on a substrate;
forming a buffer layer on the substrate to cover the first electrode;
forming an active layer on the buffer layer;
forming a gate insulating layer on the buffer layer to cover the active layer;
disposing a mask on the gate insulating layer, the mask overlapping a part of each of the active layer and the first electrode;
etching the gate insulating layer using the mask to expose another part of the active layer and to form a contact hole penetrating the gate insulating layer and the buffer layer, the contact hole exposing a part of the first electrode; and
forming a gate electrode and a second electrode on the gate insulating layer, the gate electrode overlapping the part of the active layer, the second electrode being electrically connected to the part of the first electrode through the contact hole.

18. The method of claim 17, further comprising:
before the forming of the buffer layer, forming a barrier layer on the substrate to cover the first electrode and forming a bottom gate electrode on the barrier layer,
wherein the buffer layer is formed on the barrier layer to cover the bottom gate electrode.

19. The method of claim 18, wherein the contact hole is formed to penetrate the gate insulating layer, the buffer layer, and the barrier layer.

20. The method of claim 17, wherein the etching of the gate insulating layer using the mask forms a first gate insulating layer overlapping the part of the active layer and a second gate insulating layer overlapping the part of the first electrode.
